(19) United States
(12) Patent Application Publication
(10) Pub. No.: US 2024/0272197 A1
(43) Pub. Date: Aug. 15, 2024

(54) METHOD AND DEVICE FOR INTERFERENCE VARIABLE COMPENSATION DURING THE POSITIONING OF A SAMPLE SUPPORT

(71) Applicant: TECHNISCHE UNIVERSITÄT WIEN, Wien (AT)

(72) Inventors: Markus VALTINER, Wien (AT); Kai Alexander SCHWENZFEIER, Wien (AT)

(21) Appl. No.: 18/567,274

(22) PCT Filed: Jun. 7, 2022
(86) PCT No.: PCT/AT2022/060187

§ 371 Date: Dec. 5, 2023

(30) Foreign Application Priority Data
Jun. 7, 2021 (AT) A 50458/2021

(51) Int. Cl. G01Q 30/20; G02B 21/00

(52) U.S. Cl. CPC G01Q 30/20; G02B 21/0028

(57) ABSTRACT

A method and device for interference variable compensation during the positioning of a sample support during probe microscopy. The method includes measuring a distance to a first side of the sample support using a first distance sensor of a sensor support, and measuring a distance to a second side of the sample support opposite the first side using a second distance sensor of the sensor support, the distances being determined substantially in parallel with a first axis; measuring a distance to a third side of the sample support using a third distance sensor of the sensor support, and measuring a distance to a fourth side of the sample support opposite the third side using a fourth distance sensor of the sensor support, the distances being determined substantially in parallel with a second axis different from the first axis; positioning the sample support relative to the sensor support using a piezopositioner.

The invention relates to a method and a device for interference variable compensation during the positioning of a sample support.

The exact positioning of a sample support is required, for example, in probe microscopy measurements, in semiconductor technology in the setup of mask and wafer, and in single-crystal tomography.

Probe microscopy measurements use special probes (e.g. scanning force microscopy: fine needle; scanning tunnelling microscopy: fine, electrically conductive wire tip; optical tweezers: particles in the focal point of a focused laser) in order to measure and/or image their interaction with a sample with a high local resolution of up to 0.01 nm.

The interaction of the probe with the sample depends on the relative position of the probe with respect to the sample. All apparatuses of this type show characteristic drift phenomena that change, the relative position of the probe to the sample in a non-linearly way. Drift is caused by thermal expansion/contraction of the structural components of the apparatuses, or by mechanical relaxation of joined component elements. The inaccuracy of the probe position associated with the drift occurs in all three spatial directions, represents an interference variable in the positioning of the probe support or the probe and, depending on the design, is 4-5 orders of magnitude per minute above the theoretically achievable resolution of 0.01 nm. This makes highly accurate time-invariant positioning and reproducible measurement at a position defined in real-time with nanometre-precision over periods of minutes to hours impossible.

Various methods are known from the prior art for compensating for these drift effects: structural measures comprise, for example, the use of construction materials with low thermal expansion, minimisation of connections based on static friction or symmetrical construction. Other measures also comprise insulation of sound, stabilisation against changes temperature or avoidance of vibrations through structural measures of the room that houses the apparatus. Less laborious methods include software solutions such as adaptations in the measurement protocol that contain redundancies and known markers, as well as software-supported corrections after measurement. Methods of real-time correction are technically implemented via additional sample markers, which can be located by means of additional sensor systems.

A disadvantage of the aforementioned methods is that they are very expensive (structural and non-structural measures), they can increase the measuring time so that time-critical measuring problems are excluded (additional redundancies), or they have the effect that the measurement no longer corresponds to the measuring task because the desired relative position cannot be maintained (subsequent correction). Another disadvantage of the established correction methods in real time by means of sample markers is that the solution must be specifically integrated into the measurement method and the sample must be adjusted and adapted to this. This step is not generally valid, i.e. not all sample systems allow the application of markers and potential drift of the detection system itself is ignored.

These problems generally occur with the exact positioning of sample supports.

US 2013/0098274 A1 shows a sample device in which the distance to a sample table in the x-direction and in the y-direction is determined with laser interferometers. Disadvantageously, however, thermal expansion of the sample table cannot be compensated because it cannot be determined.

The object of the invention is to alleviate or eliminate at least one of the disadvantages of the prior art. In particular, the invention is based on the object of providing a method and a device in which interference variable (s) (in particular thermal drift and thermal expansion) independent of the method are compensated for with respect to the positioning of a sample support relative to a sensor support (in particular in real time), preferably without requiring a particular nature of the sample.

This object is achieved by a method for interference variable compensation during the positioning of a sample support (relative to a sensor support), in particular in probe microscopy, having the steps of:
measuring a distance with a first distance sensor of the sensor support to a first side of the sample support and measuring a distance with a second distance sensor of the sensor support to a second side of the sample support opposite the first side, wherein the distances are determined substantially in parallel to a first axis;
measuring a distance with a third distance sensor of the sensor support to a third side of the sample support and measuring a distance with a fourth distance sensor of the sensor support to a fourth side of the sample support opposite the third side, wherein the distances are determined substantially in parallel to a second axis different from the first axis;
positioning the sample support relative to the sensor support using a piezo positioner.

Furthermore, the object is achieved by a device for interference variable compensation during the positioning of a sample support (relative to a sensor support), wherein the device comprises:
the sample support;
a sensor support with
a first distance sensor for measuring the distance to a first side of the sample support and a second distance sensor for measuring the distance to a second side of the sample support opposite the first side,
a third distance sensor for measuring the distance to a third side of the sample support and a fourth distance sensor for measuring the distance to a fourth side of the sample support opposite the third side,
wherein the first and second distance sensors are configured to determine the distances substantially in parallel to a first axis, and the third and fourth distance sensors are configured to determine the distances substantially in parallel to a second axis different from the first axis; and
a piezo positioner that carries the sample support.

By measuring the distance to two opposite sides of the sample support, both a displacement, e.g. due to thermal relaxation, and an expansion of the sample support can be determined without the need for further measures such as special markings. These are determined in the direction of the first axis with the first and second distance sensors, and in the direction of the second axis with the third and fourth distance sensors. This measurement can advantageously be carried out in real time. Interference variables are understood to mean, in particular, (thermal) drift and mechanical vibration, oscillations and/or deformations.

The measurement or determination of the distance with the first distance sensor is preferably carried out in the opposite direction to the measurement or determination of the distance with the second distance sensor. The measurement or determination of the distance with the third distance sensor preferably takes place in the opposite direction d to the measurement or determination of the distance with the fourth distance sensor. Preferably, the measurement with the first distance sensor and with the second distance sensor is performed along the first axis. Preferably, the measurement with the third distance sensor and with the fourth distance sensor is performed along the second axis. The first, second, third and fourth distance sensors are configured to accurately measure a distance, preferably to less than 10 nm, particularly preferably to less than 1 nm, even more preferably to less than 0.1 nm. Distance sensors are understood to mean spacing sensors that can determine an amount of space between a sensor head and a target, in particular with an accuracy of preferably between 10⁻⁸ and 10⁻¹² m. After a calibration phase, relative changes in the measured variables can optionally be used instead of the measured variables themselves. The distance to the respective side is understood in particular to mean the amount of space between the respective distance sensor and the respective side. The sensor support carries the first distance meter, second distance meter, third distance meter and fourth distance meter. Thus, the first, second, third and fourth distance meters each measure the distance from a point of the sensor support to a point of the sample support. In particular, the first and second distance sensors measure the distance to mutually opposite edges of the sample support. The points of the sample support to which the distances are measured in each case may be particularly prepared, for example including a reflective material. The first, second, third and fourth sides are preferably different from each other. Preferably, the third side lies between the first and the second side and/or the fourth side lies between the second and the first side.

The positioning of the sample support with the piezo positioner preferably takes place on the basis of the distances determined by the first, second, third and fourth distance sensors, wherein in particular interference variables are compensated. Preferably, the positioning is carried out in such a way that an assumed centre point of the sample support, which is determined on the basis of the distances measured from both sides in each case, is moved to a predetermined (desired) centre point.

From the respective distance sensors, which measure to opposite sides of the sample support and which advantageously lie opposite one another, the relative position and relative thermal expansion of the sensor support and sample support, and thus, if they carry a probe or a sample, also of the probe and the sample itself, are determined.

Any desired supporting structure can be provided, which carries the sensor support and the piezo positioner, wherein the piezo positioner carries the sample support. The sensor support preferably has an aperture through which preferably a probe can be or is guided.

The measurement of the distance with the first distance sensor of the sensor support to the first side of the sample support and the distance with the second distance sensor of the sensor support to the second side of the sample support is preferably carried out simultaneously. The measurement of the distance with the third distance sensor of the sensor support to the third side of the sample support and the distance with the fourth distance sensor of the sensor support to the fourth side of the sample support is preferably carried out simultaneously. Preferably, the measurements of the distances are carried out simultaneously with the first, second, third and fourth distance sensors.

The fact that the first and second axes are different from each other is understood in particular to mean that the first and second axes are not parallel to each other and are not identical to each other.

It is advantageous if the position and extent of the sample support along (i.e. in the direction of) the first axis are determined from the distances parallel to the first axis and/or the position and extent along (i.e. in the direction of) the second axis are determined from the distances parallel to the second axis. Preferably, the sample support is positioned based on the determined position (s) and direction(s) along the first and/or second axis.

It is advantageous if the method further comprises:
measuring a distance to the sample support with a fifth distance meter of the sensor support, wherein the distance is determined substantially in parallel to a third axis different from the first axis and the second axis, preferably determining the position of the sample support along the third axis. If, for example, the position and extent in each horizontal direction are determined with the first to fourth distance sensors, the position in the vertical direction can also be determined with the fifth distance meter. Since the sample is usually arranged on the sample support and extends in the direction of the first axis and the second axis on the sample support, the extent of the sample support in the direction of the third axis does not necessarily have to be determined. This usually does not affect the position of a sample provided on the sample support and a probe. Thus, absolute positioning of the sample support can be achieved with the first to fifth distance sensors. The preferred embodiments mentioned in connection with the first to fourth distance sensors may also be provided for the fifth distance sensor. Preferably, the sample support is also positioned on the basis of the distance determined by the fifth distance sensor. The measurement of the distance with the fifth distance sensor is preferably carried out simultaneously with the measurements of the distances with the first, second, third and/or fourth distance sensors.

The fact that the third axis is different from the first axis and the second axis is understood in particular to mean that the third axis and the first axis are not parallel to each other and are not identical to each other and that the third axis and the second axis are not parallel to each other and are not identical to each other.

It is advantageous if the method further comprises:
measuring a distance to the sample support with a sixth distance meter of the sensor support and with a seventh distance meter of the sensor support, wherein the distances are determined substantially in parallel to the third axis, wherein preferably a tilting about a first tilting axis of the sample support is determined from the distances determined by the sixth distance meter and by the seventh distance meter and/or a tilting about a second tilting axis of the sample support is determined from the distances determined by the fifth distance meter, sixth distance meter and seventh distance meter. For example, a tilt angle of the sample support about the first tilt axis can be determined from a relative change in distance measured by the sixth and seventh distance sensors and/or a tilt angle (inclination angle) along the second tilt axis can be determined from the relative change in distance measured by the fifth distance sensor and the mean one of the sixth and seventh distance sensors. The first and second tilt axes are preferably orthogonal to each other. Preferably, the first tilt axis is parallel to the first axis and the second tilt axis is parallel to the second axis. Preferably, the sixth and seventh distance sensors are spaced apart from one another in a direction orthogonal to the first tilt axis (or to a parallel one to the first tilt axis). Preferably, the axes along which the fifth, sixth and seventh distance sensors determine the distances are not in one plane. Preferably, the fifth, sixth and seventh distance sensors each measure the distances in the same direction (i.e. to the same side of the sample support). The preferred embodiments described in connection with the first to fifth distance sensors may also be provided in connection with the sixth and/or seventh distance sensors. Advantageously, the positioning of the sample support with the piezo positioner also takes place on the basis of the distance measured by the sixth and seventh distance sensors. Preferably, the positioning of the sample support with the piezo positioner takes place on the basis of a determined position in the direction of the third axis and/or on the basis of a determined tilt angle about the first tilt axis and/or on the basis of a determined tilt angle about the second tilt axis. The measurements of the distances with the fifth distance sensor, the sixth distance sensor and the seventh distance sensor are preferably carried out simultaneously. The measurements of the distances with the first, second, third, fourth, fifth, sixth and seventh distance sensors are preferably carried out simultaneously.

It is advantageous if a closed-loop control takes place, wherein interference variables (in particular thermal drift and/or thermal expansion) in the positioning of the sample support are compensated for with the piezo positioner on the basis of the distances determined with the first distance sensor and with the second distance sensor parallel to the first axis, in particular the determined position and expansion of the sample support along the first axis, and the distances determined with the third distance sensor and with the fourth distance sensor parallel to the second axis, in particular the determined position and expansion of the sample support along the second axis, and preferably the distance determined with the fifth distance sensor parallel to the third axis, in particular the determined position of the sample support along the third axis, and optionally the distances determined with the fifth distance sensor and/or sixth distance sensor and/or seventh distance sensor parallel to the third axis.

It is advantageous if the closed-loop control comprises that a tilting of the sample support about the first tilt axis and/or the second tilt axis (which was determined in particular with the fifth, sixth and seventh distance sensors) is compensated by the piezo positioner. With the closed-loop, the sample support is preferably brought or held at a predetermined position and preferably at a predetermined tilt.

It is advantageous if the first axis is substantially orthogonal to the second axis and preferably the first axis is substantially orthogonal to the third axis and preferably the second axis (y) is substantially orthogonal to the third axis (z). In particular, the first axis and the second axis, and preferably the third axis, are not parallel to each other.

It is advantageous if the first axis and the second axis run substantially horizontal and preferably the third axis runs substantially vertical.

It is advantageous if the first distance sensor, the second distance sensor, the third distance sensor and the fourth distance sensor (and preferably the fifth distance sensor, and preferably the sixth and seventh distance sensors) are each operated at a detection rate of between 0.2 Hz and 10 MHz, preferably between 1 Hz and 1 MHZ, and the positioning of the sample support by the piezo positioner takes place at a control rate of between 0.2 Hz and 10 MHZ, preferably between 1 Hz and 1 MHz. Thus, the interference variable compensation takes place practically in real time.

It is advantageous for the sample support to carry a sample and for the sensor support to carry a probe for interacting with the sample. Advantageously, the method is part of a method for probe microscopy, in particular for scanning force microscopy, scanning tunnelling microscopy or as optical tweezers. These can be carried out with the method according to the invention with particularly high accuracy and quality, since interference variables are compensated for particularly well.

With reference to the device according to the invention, it is advantageous if the device has a control unit, wherein the device is configured to perform the method according to the invention (according to one of the embodiments). In particular, the control unit is configured to control the remaining components of the device for carrying out the method according to the invention (according to one of the embodiments) or to receive signals from these.

It is advantageous if the first distance sensor, second distance sensor, third distance sensor and/or fourth distance sensor (and preferably the fifth, sixth and/or seventh distance sensor) are each a capacitive distance sensor or an interferometric distance sensor. With these, a particularly accurate measurement and thus interference variable compensation can be achieved.

It is advantageous if the first distance sensor, second distance sensor, third distance sensor and/or fourth distance sensor (and preferably the fifth, sixth and/or seventh distance sensors) are each a laser interferometric distance sensor. Preferably, the sample support has reflective surfaces, on which laser beams of the distance sensors are aligned in each case.

It is advantageous if the device comprises:
a fifth distance sensor for measuring the distance to the sample support,
preferably a sixth distance sensor for measuring the distance to the sample support,
preferably a seventh distance sensor for measuring the distance to the sample support,
wherein the fifth distance sensor, preferably the sixth distance sensor, and preferably the seventh distance sensor are configured to determine the distances substantially in parallel to a third axis different from the first axis and the second axis.

The invention will be explained in more detail below on the basis of particularly preferred exemplary embodiments, to which, however, it shall not be limited, and with reference to the drawings.

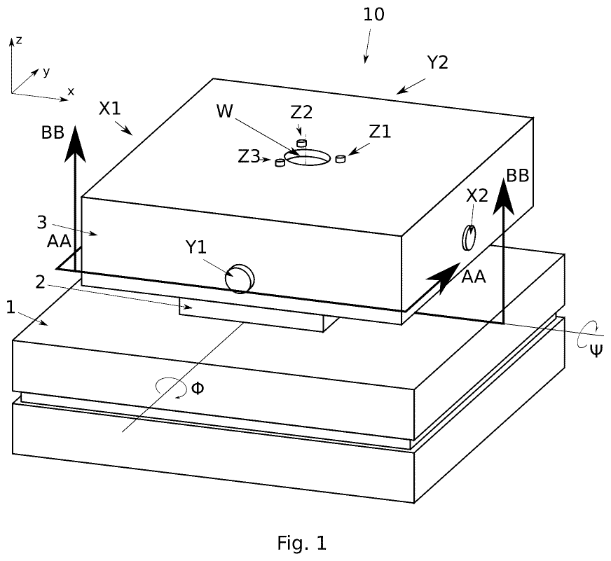

FIG. 1 schematically shows a preferred embodiment of the device for interference variable compensation obliquely from above.

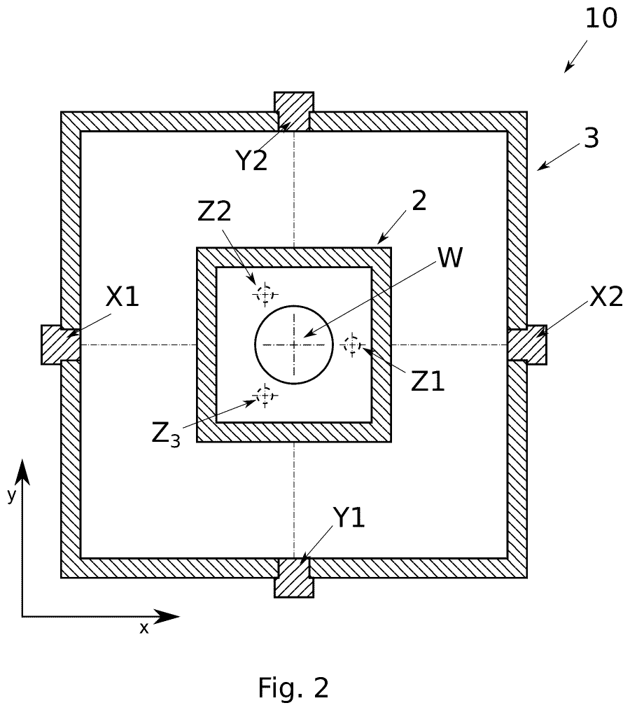

FIG. 2 schematically shows the same embodiment of the device as FIG. 1 in a section along the plane AA in FIG. 1.

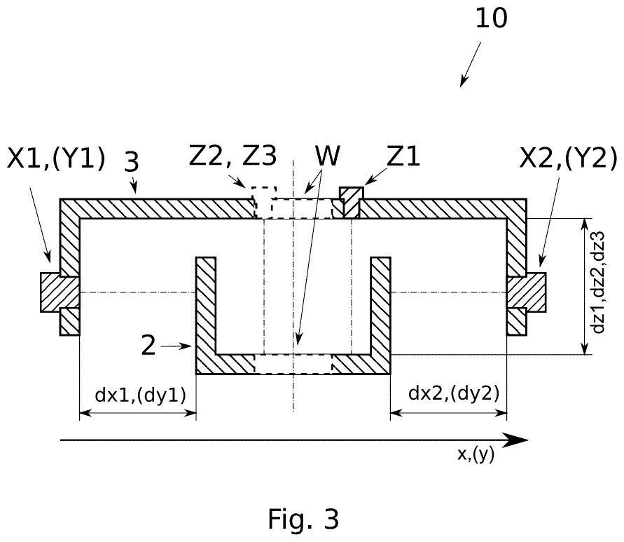

FIG. 3 schematically shows the same embodiment of the device as FIG. 1 in a section along the plane BB in FIG. 1.

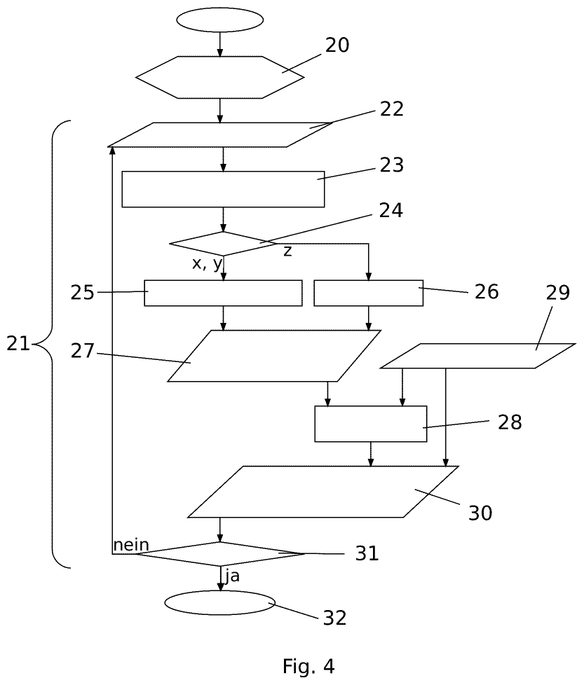

FIG. 4 illustrates, in a flow chart, a preferred embodiment of the interference variable compensation method.

FIGS. 1, 2 and 3 schematically show a preferred embodiment of a device 10 for interference variable compensation during the positioning of a sample support 2. FIG. 1 shows the device 10 obliquely from above, FIG. 2 shows the device 10 in a sectional view along the plane AA in FIG. 1, and FIG. 3 shows the device 10 in a sectional view along the plane BB in FIG. 1. In FIG. 3, the reference numbers for a section through a plane orthogonal to AA and BB in FIG. 1 are also indicated in brackets.

The device 10 comprises the sample support 2, a sensor support 3 and a piezo positioner 1, which carries the sample support 2. In FIG. 1, a first axis x, a second axis y and a third axis z form an orthogonal coordinate system. The sensor support 3 at least partially surrounds the sample support 2 in the direction of the first axis x and the second axis y.

The sensor support 3 comprises a first distance sensor X1 for measuring the distance dx1 to a first side of the sample support 2 and a second distance sensor X2 for measuring the distance dx2 to a second side of the sample support 2 opposite the first side. Furthermore, the sensor support 3 comprises a third distance sensor Y1 for measuring the distance dy1 to a third side of the sample support 2 and a fourth distance sensor Y2 for measuring the distance dy2 to a fourth side of the sample support 2 opposite the third side. The first and second distance sensors X1, X2 are configured to determine the distances dx1, dx2 substantially in parallel to the first axis x, and the third and fourth distance sensors Y1, Y2 are configured to determine the distances dy1, dy2 substantially in parallel to the second axis y. The first distance sensor X1 measures in the opposite direction to the second distance sensor X2 and the third distance sensor Y1 measures in the opposite direction to the fourth distance sensor Y2. By measuring from both sides, both thermal drift and thermal expansion in the direction of the first axis x and in the direction of the second axis y can be detected and compensated.

The sensor support 3 also comprises a fifth distance sensor Z1 for measuring the distance dz1 to the sample support 2, a sixth distance sensor Z2 for measuring the distance dz2 to the sample support 2, and a seventh distance sensor Z3 for measuring the distance dz3 to the sample support 2. The fifth distance sensor Z1, the sixth distance sensor Z2 and the seventh distance sensor Z3 are configured to determine the distances dz1, dz2, dz3 substantially in parallel to the third axis z. With these, both the vertical position of the sample support 2 relative to the sensor support 3 and the tilt or inclination of the sample support 2 can be determined. In particular, the distances dz2, dz3 are determined substantially in parallel to the third axis z, wherein a tilting about a first tilting axis Y of the sample support 2 is determined from the distances dz2, dz3 determined by the sixth distance meter Z2 and the seventh distance meter Z3, and a tilting about a second tilting axis Φ of the sample support 2 is determined from the distances dz1, dz2, dz3 determined by the fifth distance meter Z1, the sixth distance meter Z2 and the seventh distance meter Z3.

The sensors are thus divided into groups and subgroups depending on the task and spatial direction. The horizontal sensors X1, X2, Y1, Y2 are used for the simultaneous real-time determination of the relative lateral position of the sample support 2 to the sensor support 3 as well as the current thermal expansion of the sample support 2. The vertical sensors Z1, Z2, Z3 are used for the simultaneous real-time determination of the relative vertical position of the sample support 2 relative to the sensor support 3 and the relative tilting of the sample support 2. This ensures a temporally constant absolute positioning of sample support 2 and sensor support 3 relative to each other in real time.

The coordinate system formed by the first axis x, second axis y and third axis z preferably corresponds to the coordinate system of the piezo positioner 1. According to the invention, the relative position of sensor support 3 and sample support 2, and thus possibly of a probe and a sample itself, relative position and relative thermal expansion are determined from sensors that are opposite one another in pairs.

The measured distance dz1, dz2, dz3 of the vertical distance sensors Z1, Z2, Z3 preferably runs counter to the z-axis of the piezo positioner 1 and is corrected accordingly. The tilt angle about the first tilt axis Ψ is determined from the relative change in distance of dz2 and dz3, while the inclination angle about the second tilt axis Φ is determined from the relative change in distance of dz1 and the mean one between dz2 and dz3. The piezo positioner used preferably has degrees of tilt and inclination freedom, so that tilting between sample support 2 and sensor support 3 is both checked and corrected by means of the first tilt axis Ψ and the second tilt axis Φ.

The sensor support 3 and the sample support 2 each preferably have an aperture W through which, for example, a probe can be guided. In addition to determining the vertical relative position in the direction of the first axis x and the second axis y, there is the possibility of a slower reference measurement by means of white light interferometry over the path of the apertures W on a sample system.

The interference variable compensation preferably takes place in a closed-loop control, wherein interference variables in the positioning of the sample support 2 (i.e. deviations of the sample support 2 from a predetermined/desired position) are compensated (i.e. balanced by movement of the sample support 2 with the piezo positioner 1 relative to the sensor support 3) with the piezo positioner 1 on the basis of the distances dx1, dx2 determined with the first distance sensor X1 and with the second distance sensor X2 parallel to the first axis x, in particular the determined position and extent of the sample support 2 along the first axis x, and the distances dy1, dy2 determined with the third distance sensor Y1 and with the fourth distance sensor Y2 parallel to the second axis y, in particular the determined position and extent of the sample support 2 along the second axis y, and the distances dz1, dz2, dz3 determined with the fifth distance sensor Z1 and/or sixth distance sensor Z2 and/or seventh distance sensor Z3 parallel to the third axis x. Furthermore, the closed-loop control comprises that a tilting of the sample support 2 about the first tilt axis Ψ and/or the second tilt axis Φ is compensated by the piezo positioner 1.

To control the rest of the device, a control unit can be provided, in particular, which receives the signals from the distance sensors X1, X2, Y1, Y2, Z1, Z2, Z3 and controls the piezo positioner accordingly, in order to eliminate deviations of the sample support 2 from predetermined values.

FIG. 4 illustrates, in a flow chart, a preferred embodiment of the interference variable compensation method. First, the axes can be aligned and calibrated 20. Subsequently, a closed-loop control 21 is carried out, which comprises the following steps:
measuring 22 the distances dx1, dx2, dy1, dy2, dz1, dz2, dz3 with the first to seventh distance sensors X1, X2, Y1, Y2, Z1, Z2, Z3 along the associated first axis x, second axis y or third axis z and reading the distance sensors X1, X2, Y1, Y2, Z1, Z2, Z3;
assigning 23 the data channels to the respective axes x, y, z and aligning them to the coordinate system of the piezo positioner 1;
differentiating 24 according to the axis types, wherein in the case of the first axis x and the second axis y, the position and the thermal expansion of the sample support 2 in the direction of the respective axis x, y are determined 25 and in the case of the third axis z, the position of the sample support 2 in the direction of the third axis is determined 26 and the tilt angles about the first tilt axis Y and about the second tilt axis @ are determined;
representing 27 the determined data (position, extent and tilt angle) and logging of the data;
for active position control 28, a comparison of the data with predetermined set values 29 takes place and, based on this, the setting 30 of new position data for the piezo positioner 1;
deciding 31 whether the method should be ended 32 or the steps repeated.

1. A method for interference variable compensation during the positioning of a sample support, in particular during probe microscopy, comprising the following steps:
measuring a distance with a first distance sensor of the sensor support to a first side of the sample support and measuring a distance with a second distance sensor of the sensor support to a second side of the sample support opposite the first side, wherein the distances are determined substantially in parallel to a first axis;
measuring a distance with a third distance sensor of the sensor support to a third side of the sample support and measuring a distance with a fourth distance sensor of the sensor support to a fourth side of the sample support opposite the third side, wherein the distances are determined substantially in parallel to a second axis different from the first axis; and
positioning the sample support relative to the sensor support using a piezo positioner.

2. The method according to claim 1, wherein the position and the extent of the sample support along the first axis are determined from the distances parallel to the first axis, and/or wherein the position and the extent along the second axis are determined from the distances parallel to the second axis.

3. The method according to claim 1, further comprising the following steps:
measuring a distance to the sample support using a fifth distance meter of the sensor support, the distance being determined substantially in parallel to a third axis different from the first axis and the second axis, preferably determining the position of the sample support along the third axis.

4. The method according to claim 3, further comprising the following steps:
measuring a distance to the sample support with a sixth distance meter of the sensor support and with a seventh distance meter of the sensor support, wherein the distances are determined substantially in parallel to the third axis, wherein preferably a tilting about a first tilting axis of the sample support is determined from the distances determined by the sixth distance meter and by the seventh distance meter and/or a tilting about a second tilting axis of the sample support is determined from the distances determined by the fifth distance meter, sixth distance meter and seventh distance meter.

5. The method according to claim 1, wherein a closed-loop control is carried out, wherein interference variables in the positioning of the sample support are compensated for with the piezo positioner on the basis of
the distances determined with the first distance sensor and with the second distance sensor parallel to the first axis, in particular the determined position and extent of the sample support along the first axis, and
the distances determined with the third distance sensor and with the fourth distance sensor parallel to the second axis, in particular the determined position and extent of the sample support along the second axis and
optionally the distances determined with the fifth distance sensor and/or sixth distance sensor and/or seventh distance sensor parallel to the third axis.

6. The method according to claim 4, wherein the closed-loop control comprises compensating for tilting of the sample support about the first tilt axis and/or the second tilt axis by the piezo positioner.

7. The method according to claim 1, wherein the first axis is substantially orthogonal to the second axis and preferably the first axis is substantially orthogonal to the third axis and preferably the second axis is substantially orthogonal to the third axis.

8. The method according to claim 1, wherein the first axis and the second axis run substantially horizontal and preferably the third axis runs substantially vertical.

9. The method according to claim 1, wherein the first distance sensor, the second distance sensor, the third distance sensor and the fourth distance sensor are each operated at a detection rate of between 1 Hz and 1 MHz and the positioning of the sample support by the piezo positioner takes place at a control rate of between 1 Hz and 1 MHz.

10. The method according to claim 1, wherein the sample support carries a sample and the sensor support carries a probe for interacting with the sample.

11. A device for interference variable compensation during the positioning of a sample support comprising:
the sample support;
a sensor support with
a first distance sensor for measuring the distance to a first side of the sample support and a second distance sensor for measuring the distance to a second side of the sample support opposite the first side;
a third distance sensor for measuring the distance to a third side of the sample support and a fourth distance sensor for measuring the distance to a fourth side of the sample support opposite the third side;
wherein the first and second distance sensors are configured to determine the distances substantially in parallel to a first axis, and the third and fourth distance sensors are configured to determine the distances substantially in parallel to a second axis different from the first axis; and
a piezo positioner that carries the sample support.

12. The device according to claim 11, comprising a control unit, wherein the device is configured to carry out a method comprising: measuring a distance with a first distance sensor of the sensor support to a first side of the sample support and measuring a distance with a second distance sensor of the sensor support to a second side of the sample support opposite the first side, wherein the distances are determined substantially in parallel to a first axis;
measuring a distance with a third distance sensor of the sensor support to a third side of the sample support and measuring a distance with a fourth distance sensor of the sensor support to a fourth side of the sample support opposite the third side, wherein the distances are determined substantially in parallel to a second axis different from the first axis; and
positioning the sample support relative to the sensor support using a piezo positioner.

13. The device according to claim 11, wherein the first distance sensor, second distance sensor, third distance sensor and/or fourth distance sensor are each a capacitive distance sensor or an interferometric distance sensor.

14. The device according to claim 13, wherein the first distance sensor, second distance sensor, third distance sensor and/or fourth distance sensor are each a laser interferometric distance sensor.

15. The device according to claim 11, wherein the sensor support comprises:
a fifth distance sensor for measuring the distance to the sample support,
preferably a sixth distance sensor for measuring the distance to the sample support,
preferably a seventh distance sensor for measuring the distance to the sample support,
wherein the fifth distance sensor, preferably the sixth distance sensor, and preferably the seventh distance sensor are configured to determine the distances substantially in parallel to a third axis different from the first axis and the second axis.
